(19) United States
(12) Patent Application Publication
(10) Pub. No.: US 2011/0260015 A1
(43) Pub. Date: Oct. 27, 2011

(54) VISUAL PRESENTING APPARATUS

(75) Inventors: Hiroshi Yamakose, Aichi (JP); Akihisa Ohta, Aichi (JP)

(73) Assignee: Elmo Co., Ltd., Nagoya-shi (JP)

(21) Appl. No.: 13/090,289

(22) Filed: Apr. 20, 2011

(30) Foreign Application Priority Data
Apr. 27, 2010 (JP) 2010-102292

(51) Int. Cl. H05K 7/00

(52) U.S. Cl. 248/157

(57) ABSTRACT

A visual presenting apparatus includes a support column which is mounted via a pivot shaft on a base so as to be pivotable, a friction braking mechanism applying a frictional load to the pivot shaft over a whole range of pivotal movement of the column, a power assist mechanism which applies a spring force to the column to urge the column rearward, a video camera head mounted on a distal end of the column and located over a document placed on an installation surface of the base, thereby imaging the document. The column is pivotable between a forwardly-tilted position and a folded position. The power assist mechanism is operatively coupled with the column when the column is tilted forward from an upright position. The power assist mechanism is released from the coupled state when the column is tilted rearward from the upright position.

### CROSS-REFERENCE TO RELATED APPLICATIONS

This application is based upon and claims the benefit of priority from the prior Japanese Patent Application No. 2010-102292, filed on Apr. 27, 2010 the entire contents of which are incorporated herein by reference.

### BACKGROUND

1. Technical Field

The present disclosure relates to a visual presenting apparatus which includes a base, a support column mounted on the base and a video camera head mounted on a distal end of the support column and in which a material such as documents or models is imaged by the video camera head so that an obtained image is supplied to a TV monitor or projected by a video projector onto a screen.

2. Related Art

Japanese Patent Application Publication JP-A-2007-180713 discloses a visual presenting apparatus of the above-described type. The visual presenting apparatus includes a generally book-shaped base, a generally inverted J-shaped support column and a horizontally-long cylindrical video camera head. The support column has a proximal end which is mounted on a pivot shaft further mounted on a central front of the base so that the support column is pivotable in a front-rear direction. As a result, the support column is pivotable between an upright position where the support column stands generally upright on the base and a forwardly-tilted position where the support column is tilted forward from the base so as to be substantially adjacent to an installation surface on which the visual presenting apparatus is installed.

The proximal end of the support column is provided with a friction braking mechanism which applies a predetermined friction braking force to the pivot shaft over a whole range of pivotal movement of the support column and a power assist mechanism which applies to the support column a spring force urging the support column rearward, whereby the friction braking force, the spring force and the gravity force acting on the support column are normally balanced with one another.

The support column is retained at an arbitrary forwardly-tilted position within the pivotal movement range thereof by the friction braking mechanism and the power assist mechanism in the above-described visual presenting apparatus. Furthermore, the friction braking force, the spring force and the gravity force are balanced with one another both when the support column pivots from the upright position to the forwardly-tilted position and when the support column pivots from the forwardly-tilted position to the upright position. Accordingly, a force causing the support column to pivot is so small as to be easily settable to a desired forwardly-tilted position.

The pivotal movement range of the support column is set between the upright and forwardly-tilted positions in the above-described conventional visual presenting apparatus as described above. However, the support column is disallowed to pivot rearward from the upright position. Thus, since the support column cannot be laid rearward along the base, the support column is retained either at the upright position where the support column stands upright on the base or the forwardly-tilted position where the support column protrudes forward from the base, even when the visual presenting apparatus is not in use. Thus, the support column cannot be folded into such a compact shape that the support column is laid along the base.

On the other hand, in order that the visual presenting apparatus may be folded into a more compact form, the pivotal movement range of the support column has been proposed to be enlarged so that the support column pivots from the forwardly-tilted position through the upright position to a laid position where the support column is laid along the base. In this case, the spring force of the power assist mechanism would act in the same direction as the gravity force between the upright position and the laid position although acting in a direction against the gravity force between the forwardly-tilted position and the upright position. As a result, when the support column occupying the forwardly-titled position is raised upward so that the visual presenting apparatus is folded, the gravity force and the spring force would act in the same direction when the support column passes through the upright position, whereupon the support column would have a possibility of inadvertent rapid pivoting. This would necessitate careful pivoting of the support column. Furthermore, when the support column assuming the laid position is raised upward, the support column needs to be operated to pivot against the three forces, that is, the friction braking force, the spring force and the gravity force, whereupon the operability of the support column is extremely reduced.

### SUMMARY

Therefore, an object of the present disclosure is to provide a visual presenting apparatus which can be folded into a more compact form when the visual presenting apparatus is not in use, by rendering the support column capable of pivoting between the forwardly-tilted position and the laid position and in which the support column can easily pivot thereby to improve the usability of the visual presenting apparatus.

The present disclosure provides a visual presenting apparatus comprising a base, a support column which is mounted via a pivot shaft on the base so as to be pivotable in a front-rear direction, a friction braking mechanism which applies a predetermined frictional load to the pivot shaft over a whole range of pivotal movement of the support column, a power assist mechanism which applies a spring force to the support column thereby to urge the support column rearward, and a video camera head which is mounted on a distal end of the support column and disposed over a document placed on an installation surface of the base, thereby imaging the document. In the apparatus, the support column mounted on the base is pivotable between a forwardly-tilted position where the support column stands at a forward tilt angle relative to the base and a folded position where the support column is laid rearward along the base. The power assist mechanism is operatively coupled with the support column when the support column is tilted forward from an upright position where the support column stands substantially upright on the base. The power assist mechanism being released from the operatively coupled state with the support column when the support column is tilted rearward from the upright position.

In the above-described visual presenting apparatus, the support column can be operated to pivot to rearward of the base thereby to be laid along the base. Consequently, the apparatus can be folded into a more compact state. Furthermore, the power assist mechanism is operatively coupled with the support column when the support column is tilted forward beyond the upright position. Accordingly, the friction braking force of the friction braking mechanism, the spring force of the power assist mechanism and the gravity acting on the support column are set so as to be balanced with one another in a forward-tilt range of the support column. As a result, the support column can be retained at an arbitrary forwardly-tilted position and operated to pivot more smoothly.

On the other hand, the power assist mechanism is released from the operative coupling with the support column when the support column is tilted rearward beyond the upright position. Accordingly, the spring force of the power assist mechanism does not act on the support in a pivot range where the support column is tilted rearward, and only the friction braking force and the gravity act on the support column. Consequently, the first support column can be prevented from an inadvertent rapid pivoting by the spring force of the power assist mechanism. Furthermore, the support column need not be operated to pivot against the spring force when the support column is raised upward from the laid position to the upright position. Consequently, the first support column can be raised upward smoothly.

### BRIEF DESCRIPTION OF THE DRAWINGS

FIG. 1 is a perspective view of the visual presenting apparatus in accordance with one embodiment, showing a usage state where a support column occupies a forwardly-tilted position;

FIG. 2 is a perspective view of the visual presenting apparatus in a folded state;

FIG. 3 is a perspective view of the visual presenting apparatus, showing a usage state where the support column occupies an upright position;

FIG. 4 is a perspective view showing the structure of the support column and a pivot shaft of the visual presenting apparatus; and

FIG. 5 is an exploded perspective view showing the structure of the support column and the pivot shaft.

### DETAILED DESCRIPTION

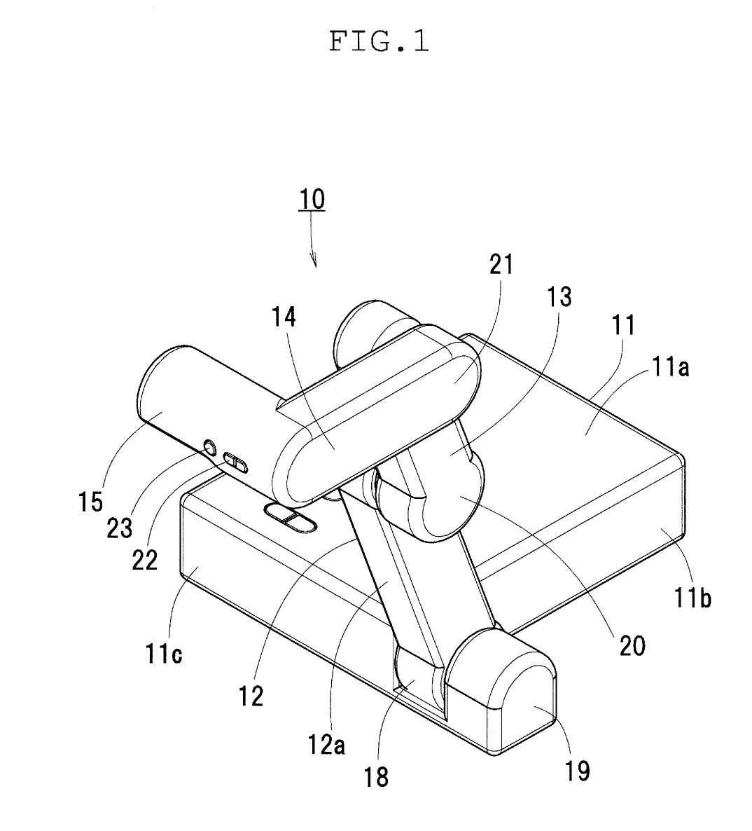

One embodiment will be described with reference to the accompanying drawings. Referring to FIGS. 1 to 3, a visual presenting apparatus 10 of the embodiment is shown. The visual presenting apparatus 10 includes a base 11, a first support column 12, a second support column 13, a third support column 14 and a video camera head 15.

The base 11 has a planar shape of a rectangular box and is formed into the shape of a thick book in a whole. The base 11 has an upper surface 11a on which various operation switches including a power switch 16 and a luminance adjustment button 17 are arranged. The base 11 has a rear on which various terminals are provided for connection of the apparatus 10 to a TV monitor, a video projector and the like, although the terminals are not shown in the drawings. The base 11 encloses therein control circuit units performing a zooming control, an autofocusing control and a luminance control for the video camera head 15 respectively. The base 11 also encloses therein balance weight which prevents the base 11 from being toppled over due to the weight of the video camera head 15.

The first support column 12 has a proximal end mounted on a first pivot shaft 18 further mounted on a front part of a side 11b of the base 11, so as to be pivotable in a front-rear direction of the apparatus 10. Thus, the first support column 12 is mounted via the first pivot shaft 18 on the base 11 so as to be pivotable in the front-rear direction. A shaft bearing 19 is formed integrally with the front part of the side 11b of the base 11. The second support column 13 has a proximal end mounted on a second pivot shaft 20 further mounted on a distal end of the first support column 12, so as to be pivotable in the front-rear direction. Thus, the second support column 13 is mounted via the second pivot shaft 20 on the first support column 12 so as to be pivotable in the front-rear direction. The third support column 14 has a proximal end mounted on a third pivot shaft 21 further mounted on a distal end of the second support column 13, so as to be pivotable in the front-rear direction. Thus, the third support column 14 is mounted via the third pivot shaft 21 on the second support column 13 so as to be pivotable in the front-rear direction.

The video camera head 15 is formed into a horizontally long cylindrical shape and has a front provided with a zoom switch 22 and an autofocus switch 23. The vide camera head 15 has one of two ends which is fixed to the distal end of the third support column 14, extending substantially in parallel to a front 11c of the base 11 in a lateral direction of the base 11. The video camera head 15 has the other end in which an imaging lens is built although the imaging lens is not shown. Wires are inserted through interiors of the first to third support columns 12 to 14 for the purpose of electrically connecting between the control circuit units and the video camera head 15 respectively.

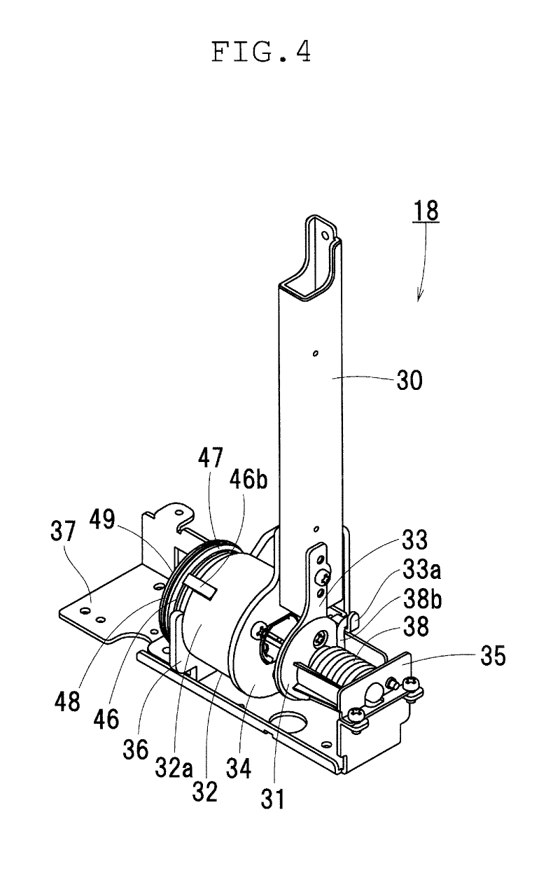

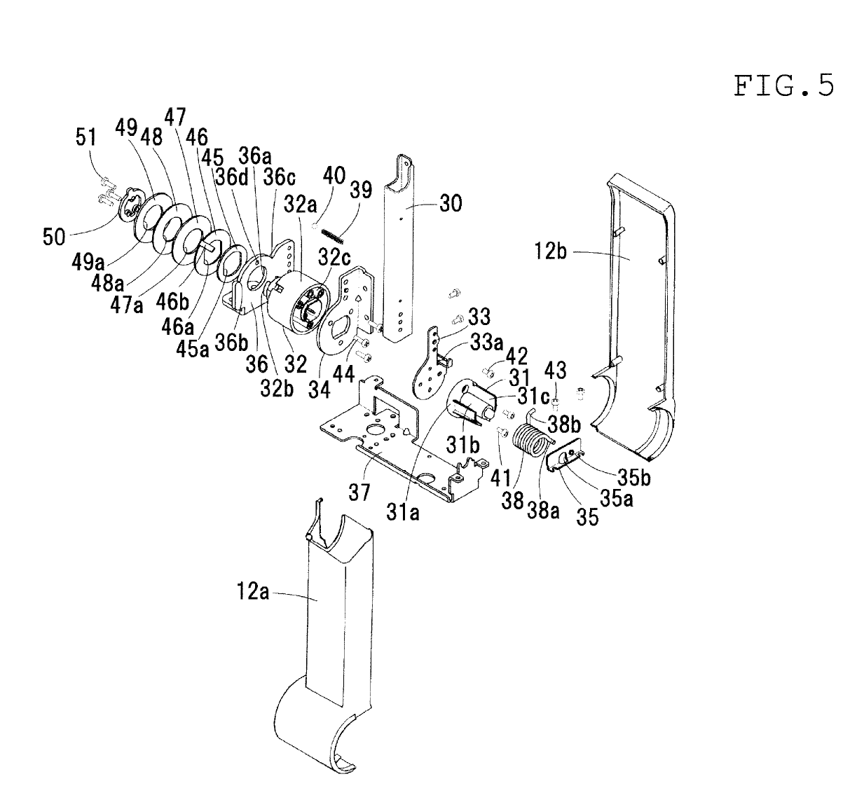

Referring now to FIGS. 4 and 5, an inner structure of the pivot shaft 18 of the first support column 12 is shown. The pivot shaft 18 includes a hollow support column frame 30 on which two covers 12a and 12b of the first support column 12 are mounted. The pivot shaft 18 further includes an outer pivot shaft 31, an inner pivot shaft 32, an outer bracket 33, an inner bracket 34, an outer bearing plate 35, an inner bearing plate 36, a base bracket 37 fixed to an underside of the base 11, a twisted spring 38, a click spring 39 and a click ball 40.

The outer pivot shaft 31 is secured to the outer bracket 33 by small screws 41. The outer bracket 33 is secured to an outer lower end of the support column frame 30 by a small screw 42. The outer pivot shaft 31 includes a circular base plate 31a, an outer shaft core 31b protruding from a central part of the base plate 31a and two guide strips 31c which protrude from the base plate 31a so as to surround shaft core 31b. The twisted spring 38 is attached to the outer shaft core 31b. The outer shaft core 31b has a distal end which is inserted into a bearing hole 35a of the outer bearing plate 35 fixed to the base bracket 37 by small screws 43. Thus, the outer pivot shaft 31 is rotatably mounted on the outer bearing plate 35. Furthermore, the twisted spring 38 has an end 38a inserted into a locking hole 35b formed in the outer bearing plate 35. The other end 38b of the twisted spring 38 is adjacent to one guide piece 31c and protrudes out of the guide piece 31c. On the other hand, the outer bracket 33 is provided with a hook strip 33a with which the other end 38b of the twisted spring 38 is engageable.

The inner pivot shaft 32 is secured to the inner bracket 34 by a small screw 44. The inner bracket 34 is secured to an inner lower end of the support column frame 30 by a small screw. The inner pivot shaft 32 includes a hollow larger-diameter shaft 32a and a smaller-diameter shaft 32b protruding inward from a central part of the larger-diameter shaft 32a. The smaller-diameter shaft 32b is inserted in a bearing hole 36a of an inner bearing plate 36 fixed to a base bracket 37 by small screws. Thus, the inner pivot shaft 32 is rotatably mounted on the inner bearing plate 36.

To the smaller-diameter shaft 32b of the inner pivot shaft 32 are attached a first washer 45, a stopper ring 46, a first disc spring 47, a second washer 48, a second disc spring 49 and a ring plate 50 sequentially. The first washer 45 and the stopper ring 46 have noncircular holes 45a and 46a respectively. The smaller-diameter shaft 32b is inserted through the noncircular holes 45a and 46a so that the first washer 45 and the stopper ring 46 are attached to the inner pivot shaft 32 so as to be rotated with the shaft 32. The stopper ring 46 has a stopper strip 46b which is formed integrally therewith and extends outward in parallel with the inner pivot shaft 32b attached. On the other hand, the stopper strip 46b abuts against the inner bearing plate 36 such that a front locking portion 36b and a rear locking portion 36c are formed. The front and rear locking portions 36b and 36c limit a pivot range of the inner pivot shaft 32 and the first support shaft 12 pivoting with the inner pivot shaft 32.

The first disc spring 47, the second washer 48 and the second disc spring 49 have circular holes 47a, 48a and 49a respectively. The smaller-diameter shaft 32 of the inner pivot shaft 32 is inserted through the circular holes 47a, 48a and 49a such that the first disc spring 47, the second washer 48 and the second disc spring 49 are mounted on the inner pivot shaft 32. The ring plate 50 is fixed to a distal end of the smaller-diameter shaft 32b by a small screw 51. The ring plate 50 thus retains the first and second washers 45 and 48, the first and second disc springs 47 and 49 and the stopper ring 46 relative to the smaller-diameter shaft 32b. Furthermore, the first and second disc springs 47 and 48 press the first washer 45 against the inner bearing plate 36 with a predetermined pressure. The clicking spring 39 and the clicking ball 40 are provided in a cylindrical bore 32c formed in the larger-diameter shaft 32a of the inner pivot shaft 32. On the other hand, the inner bearing plate 36 has a fitting hole 36d formed at a predetermined position thereof and into which the clicking ball 40 is fitted.

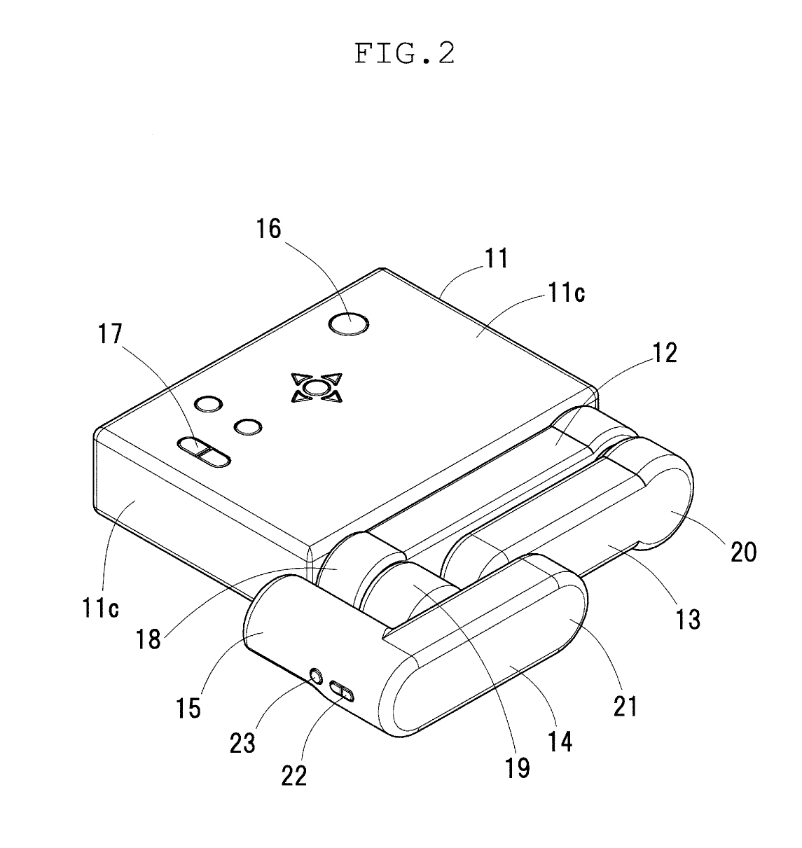

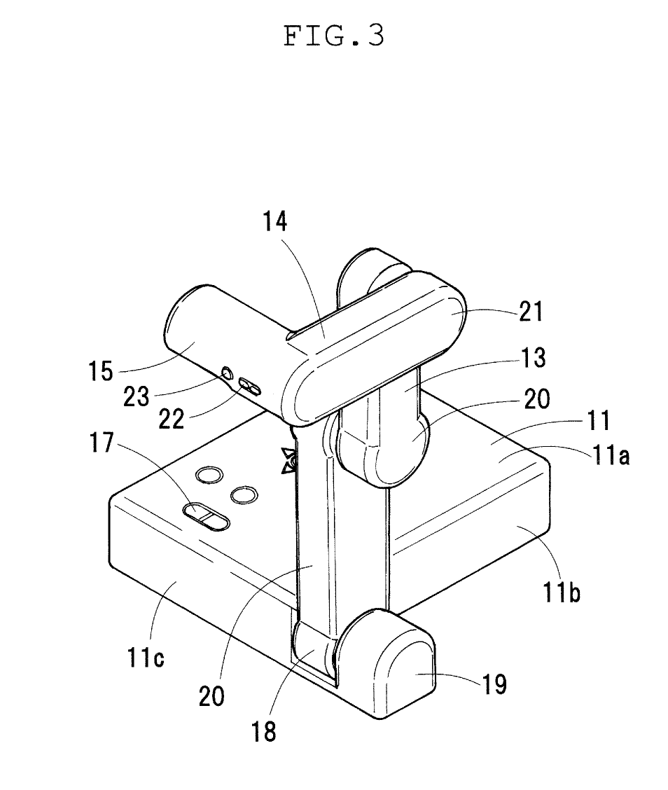

In the first pivot shaft 18 having the inner structure as described above, the column frame 30 of the first support column 12 is mounted to the base 11 with the outer and inner pivot shafts 31 and 32 being interposed therebetween, whereupon the column frame 30 is pivotable on the outer and inner pivot shafts 31 and 32 in the front-rear direction. The pivot range of the first support column 12 is limited by the front and rear locking portions 36b and 36c of the inner bearing plate 36. The first support column 12 stops at the forwardly-tilted position as shown in FIG. 1 when the stopper strip 46b is abutted against the front locking portion 36b. The first support column 12 stops at the folded position as shown in FIG. 2 when the stopper strip 46b is abutted against the rear locking portion 36c. The first support column 12 is laid along the side 11b of the base 11 when occupying the folded position. Furthermore, when the first support column 12 occupies a position where the first support column 12 stands on the base 11 substantially upright, the clicking ball 40 is fitted in the fitting hole 36d such that the first support column 12 is retained at the upright position, as shown in FIG. 3.

The twisted spring 38 and the hook strip 33a of the outer bracket 33 constitute a power assist mechanism. When the first support column 12 is forwardly tilted beyond the upright position as shown in FIG. 3, the end 38a of the twisted spring 38 and the hook strip 33a are retained in engagement with each other, whereupon the first support column 12 is urged rearward by the twisted spring 38. On the other hand, when the first support column 12 is tilted rearward beyond the upright position, the twisted spring 38 and the hook strip 33a are disengaged from each other such that no rearwardly urging force is applied to the first support column 12 by the twisted spring 38. Furthermore, when disengaged from the hook strip 33a, the twisted spring 38 abuts at the end 38b thereof against the edge of the guide strip 31c and projects outside thereby to be retained in a position where the twisted spring 38 is engageable with the hook strip 33a.

The first and second washers 45 and 48, the first and second disc springs 47 and 49 and the plate 50 constitute a friction braking mechanism, which applies a predetermined friction braking force to the first pivot shaft 18. Additionally, the friction braking mechanism is also constructed so as to apply a predetermined friction braking force to each of the second and third pivot shafts 20 and 21 although the construction is not described in detail.

When the visual presenting apparatus 10 constructed as descried above is not in use, the first support column 12 is operated to pivot rearward until the stopper strip 46b abuts against the rear locking portion 36c as shown in FIG. 2. When the stopper strip 46b abuts against the rear locking portion 36c, the first support column 12 is stopped at the folded position where the first support column 12 is laid along the side 11a of the base 11. Furthermore, the second support column 13 is also operated to pivot to the folded position where the second support column 13 is laid along the side of the first support column 12. Still furthermore, the third support column 14 is extended forward in parallel with the second support column 13.

When documents are imaged by the visual presenting apparatus 10, the base 11 is installed on an installation surface, and the TV monitor or the projector (neither shown) is connected to the base 11 by a connecting cord. The first support column 12 is operated to pivot forward from the folded position until the stopper strip 46b abuts against the front locking portion 36b. When the stopper strip 46b abuts against the front locking portion 36b, the first support column 12 stops at the forwardly-tilted position where the first support column 12 is titled forward at a largest angle relative to the upright position, as shown in FIG. 1. The second support column 13 is then operated to pivot to a position where the second support column 13 extends upward in parallel to the first support column 12. Furthermore, the third support column 14 is operated to pivot to a position where the third support column 14 is substantially parallel to the upper surface 11a of the base 11. The second and third support columns 13 and 14 are retained at respective predetermined pivot positions by the friction braking force. The first support column 12 is operated to pivot rearward from the forwardly-tilted position as shown in FIG. 1 thereby to be set to a desired forward tilt angle, as the need arises.

According to the above-described visual presenting apparatus 10, the first support column 12 can be laid along the side 11b of the base 11 when operated to pivot to rearward of the base 11. Furthermore, since the second and third support columns 13 and 14 can also be laid along the side of the base 11, the apparatus 10 can be folded into a compact state.

The power assist mechanism is operatively coupled with the first support column 12 when the first support column 12 is tilted forward beyond the upright position. Accordingly, the friction braking force of the friction braking mechanism, the spring force of the power assist mechanism and the gravity acting on the first support column 12 are all set so as to be balanced with one another in the forward-tilt pivot range of the first support column 12. As a result, the first support column 12 can be retained at an arbitrary forwardly-tilted position and operated to pivot smoothly.

On the other hand, the power assist mechanism is released from the operative coupling with the first support column 12 when the first support column 12 is tilted rearward beyond the upright position. Accordingly, the spring force of the power assist mechanism does not act on the first support column 12 in a pivotal movement range where the first support column 12 is tilted rearward, and only the friction braking force and the gravity act on the first support column 12. Consequently, the first support column 12 can be prevented from an inadvertent rapid pivoting by the spring force of the power assist mechanism. Furthermore, the first support column 12 need not be operated to pivot against the spring force when the first support column 12 is raised upward from the laid position to the upright position. Consequently, the first support column 12 can be raised upward smoothly.

The clicking mechanism includes the clicking spring 39 and the clicking ball 40. The clicking ball 40 is fitted in the fitting hole 36d when the first support column 12 occupies the upright position. Accordingly, the operator can recognize the upright position when causing the first support column 12 to pivot. Consequently, since the operator can recognize the start and termination of the operation of the power assist mechanism, the first support column 12 can easily be operated.

Additionally, the video camera head 15 may be mounted on the second support column 13 with elimination of the third support column 14 although mounted on the third support column 14 in the foregoing embodiment. Alternatively, the video camera head 15 may be mounted on the first support column 12 with elimination of the second and third support columns 13 and 14.

The foregoing description and drawings are merely illustrative and are not to be construed in a limiting sense. Various changes and modifications will become apparent to those of ordinary skill in the art. All such changes and modifications are seen to fall within the scope as defined by the appended claims.

What is claimed is:

1. A visual presenting apparatus comprising:
a base;
a support column which is mounted via a pivot shaft on the base so as to be pivotable in a front-rear direction;
a friction braking mechanism which applies a predetermined frictional load to the pivot shaft over a whole range of pivotal movement of the support column;
a power assist mechanism which applies a spring force to the support column thereby to urge the support column rearward;
a video camera head which is mounted on a distal end of the support column and disposed over a document placed on an installation surface of the base, thereby imaging the document, wherein:
the support column mounted on the base is pivotable between a forwardly-tilted position where the support column stands at a forward tilt angle relative to the base and a folded position where the support column is laid rearward along the base;
the power assist mechanism is operatively coupled with the support column when the support column is tilted forward from an upright position where the support column stands substantially upright on the base; and
the power assist mechanism being released from the operatively coupled state with the support column when the support column is tilted rearward from the upright position.

2. The apparatus according to claim 1, wherein:
the power assist mechanism includes a twisted spring having two ends and a hook strip;
one of the ends of the twisted spring is fixed to the base and the other end of the twisted spring is engaged with the hook strip; and
the hook strip is retained in engagement with the twisted spring when the support column is tilted forward beyond the upright position, and the hook strip is disengaged from the twisted spring when the support column is tilted rearward beyond the upright position.

3. The apparatus according to claim 2, further comprising a first bearing plate and a second bearing plate, wherein:
the pivot shaft has two ends and the twisted spring is attached to one of the ends of the pivot shaft, and said one end of the pivot shaft is supported by the first bearing plate fixed to the base and the other end of the pivot shaft is supported by the second bearing plate fixed to the base; and
the friction braking mechanism includes a washer fixed to said other end of the pivot shaft and a disc spring which is attached to the pivot shaft to press the washer against the second bearing plate.

4. The apparatus according to claim 1, further comprising a clicking mechanism which retains the support column at the upright position.
